(19) United States
(12) Patent Application Publication
(10) Pub. No.: US 2004/0004435 A1
(43) Pub. Date: Jan. 8, 2004

(54) Immersion cooling type light emitting diode and its packaging method

(76) Inventor: Chi-Hsing Hsu, Tao-Yuan Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/064,358

(22) Filed: Jul. 4, 2002

(51) Int. Cl. H01J 1/62

(52) U.S. Cl. 313/512

(57) ABSTRACT

An immersion cooling type diode device has a diode chip, a diode chip carrier for carrying the diode chip, a lead frame connected to the diode chip carrier, at least one metal wire bond, a base, a round-shaped transparent cap with a cylinder wall for covering the base to form a cavity, a cooling liquid filled in the cavity, and a heat sink for dissipating heat generated by the diode chip. The cooling liquid directly contacts with the diode chip and the metal wire bond, and the diode chip is either one of a light emitting diode (LED) chip, a vertical emitting type laser diode chip, an edge emitting type laser diode chip, a polymer molecule LED chip or a smaller organic molecule LED chip.

### BACKGROUND OF INVENTION

1. Field of the Invention

The present invention relates to a diode and its packaging method, and more specifically, to an immersion cooling type light emitting diode (LED) and its packaging method.

2. Description of the Prior Art

As technology progresses, it has become a trend to substitute light emitting diodes (LED) with high brightness for traditional tungsten light bulbs in the of various products such as traffic lights, Christmas decorations, information boards, exit directing signs and so on. In order to introduce LED into manufacturing processes for more consumer products, the power efficiency of the LED needs to be improved by integrating semiconductor technologies into LED manufacturing processes. In addition, the structural and functional design of LED chips needs to be upgraded, and the LED manufacturing process needs to be simplified by introducing a new packaging method with excellent heat dissipating ability of the LED chip.

Please refer to FIG. 1 of a schematic view of an LED device with high brightness according to the prior art. As shown in FIG. 1, an LED chip 11 is positioned on an LED chip carrier 17, electrically connected to a lead frame 12 by using at least one metal wire bond 13, and packed in a solid epoxy resin block 14. The heat generated during the operation of the LED chip 11 is dissipated to the air outside the LED device through the lead frame 12 connected to the LED chip carrier 17. However, the solid epoxy resin block 14 frequently break the metal wire bond 13 due to the temperature gradient of the solid epoxy resin block 14 caused by an operating current of the LED chip 11 higher than 100 mA, leading to a shortened product life of the LED device.

The LED chip 11 according to the prior art comprises P-type and N-type semiconductor materials that connected to each other to form a PN junction and emits light as a positive voltage is applied to the PN junction. The LED chip 11 is hexahedron-shaped and may be categorized into either one of two types regarding the location of the electrodes of the LED chip 11; one with the positive and negative electrodes formed on two opposite surfaces of the hexahedron, and the other with the positive and negative electrodes formed on a same surface of the hexahedron and an insulating substrate formed on the surface adjacent to the surface on which the positive and the negative electrodes are formed.

The LED chip carrier 17 is connected to the lead frame 12, and one electrode of the LED chip 11 is fixed to the LED chip carrier 17 by using a conductive adhesive, such as silver paste, tin paste and indium. The other electrode of the LED chip 11 is electrically connected to another lead frame 12 via another metal wire bond 13, enabling the LED chip 11 to electrically connect to other external circuits and devices. The lead frame 12 is composed of an electrically and heat conductive metal, such as copper, copper alloy, aluminum alloy and alloy comprising iron, cobalt and nickel, and comprises a silver-plated surface. The silver-plated surface of the lead frame 12 is employed to reinforce the adhesion of the metal wire bond 13 to the lead frame 12.

There are numerous ways packaging an LED device, please refer to FIG. 2 of the schematic view of a laser diode (LD) device according to the prior art. In comparison with the LED chip 11 shown in FIG. 1, the LD chip shown in FIG. 2 is not packaged in the solid epoxy resin block 14 but in either a sealed vacant space or a sealed nitrogen-containing space. This is the so-called TO-packaging method. Since the active junction area of the LD chip is approximately one hundred and fiftieth of the active junction area of the LED chip 11, the tolerable operating current density of the LD chip is approximately 50 to 75 times of the tolerable operating current density of the LED chip 11, leading to a much larger amount of heat generated by the LD chip during operation in comparison with the heat amount generated by the LED chip 11 during operation. The heat generated by the LD chip during operation is dissipated to the air outside the LD device via the metal base to assure the reliable electrical performance and reasonable product life of the LD device under room temperature.

Therefore, the brightness performance of the LED device packaged by a method similar to the TO-packaging method mentioned in the previous paragraph can be improved by increasing the operating current density. For instance, the operating current of the LED device named Luxeon™, comprising a bigger base composed of highly heat conductive metal and a heat sink composed of an aluminum circuit board, manufactured by Lumiled ranges from 200 to 250 mA. The LED chip of Luxeon™ is packaged in a solid silicone rubber instead of in the solid epoxy resin block shown in FIG. 1. Consequently, the total performance of 18 pieces of this Luxeon™ LED device is even better than the total performance of 150 pieces of traditional LED device in brightness, and the product life of Luxeon™ is significantly increased. According to the operating menu of Luxeon™, by applying an operating power of 1 watt (W) to one Luxeon™ device, a brightness of the Luxeon™ device ranging from 10 to 50 lumn is achieved, so that the light emitting efficiency of the Luxeon™ device is 50 lumn/1 W, which is much better than the light emitting efficiency of a traditional tungsten bulb, which is 1500 lumn/100 W only.

However, the manufacturing cost of Luxeon™ is very high, leading to a high selling price not acceptable to consumers. On the contrary, the traditional LED device has a much lower selling price, but its operating current is limited to be less than 20 mA, leading to a poor light emitting performance since the heat is generated within a small area during operation and is not easy to be evolved to the air outside the LED device.

### SUMMARY OF INVENTION

It is therefore a primary object of the present invention to provide a liquid cooling type light emitting diode (LED) device manufactured by simplified processes and composed of materials with an excellent heat dissipating ability during operation so as to achieve an improved light emitting performance by increasing the tolerable operating current density of the LED device.

According to the claimed invention, an immersion cooling type diode device comprises a diode chip, a diode chip carrier, a lead frame, at least one metal wire bond, a base, a heat sink and a round-shaped transparent cap with a cylinder wall. The diode chip is either one of a light emitting diode (LED) chip, a vertical emitting type laser diode chip, an edge emitting type laser diode chip, a polymer molecule LED chip or a smaller molecule LED chip and is positioned on the diode chip carrier. The round-shaped transparent cap with the cylinder wall is employed to cover the base, forming a cavity for a cooling liquid to be filled in, and the heat sink is used to dissipate heat generated by the diode chip.

It is an advantage of the present invention against the prior art that the LED device provided in the present invention utilizes the cooling liquid to enable the LED chip to remain at a lower temperature during the operation with a high driving current density. Therefore, the tolerable operating power and driving current density are increased to achieve an improved brightness performance of the LED device. In addition, the LED device in the present invention can be packaged by using traditional lead frames, which is with acceptable material cost and can be packaged by existent equipments without spending cost caused by the purchase for new equipments. Consequently, products with the LED device in the present invention turn to be much more competitive in the market.

These and other objectives of the present invention will no doubt become obvious to those of ordinary skill in the art after reading the following detailed description of the preferred embodiment, which is illustrated in the multiple figures and drawings.

### BRIEF DESCRIPTION OF DRAWINGS

FIG. 1 is a schematic view of a light emitting diode (LED) device of the prior art.

FIG. 2 is the schematic view of a laser diode device according to the prior art.

FIG. 3 is the schematic view of a liquid cooling type LED device according to the present invention.

FIGS. 4-8 are the schematic views of another embodiments of the liquid cooling LED device according to the present invention.

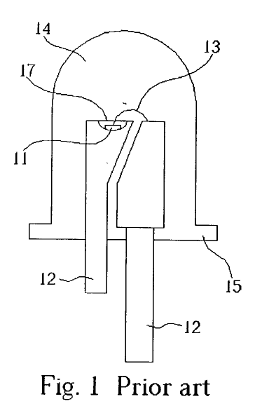

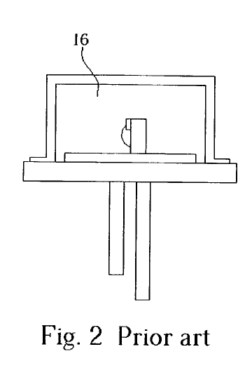

### DETAILED DESCRIPTION

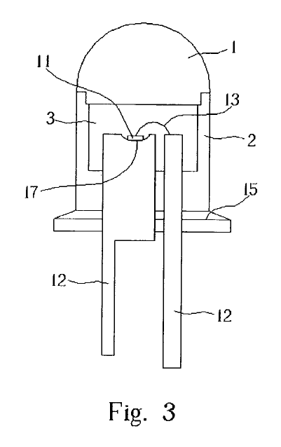

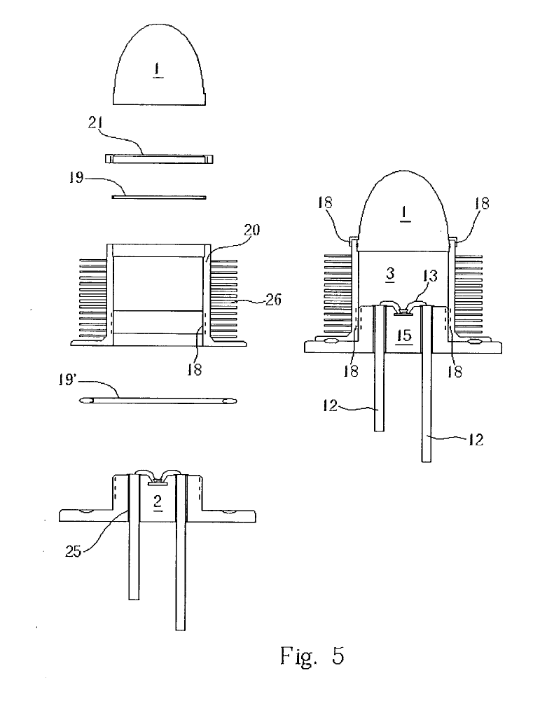

Please refer to FIG. 3 of a schematic view of a liquid cooling type light emitting diode (LED) according to the present invention. As shown in FIG. 3, an LED device comprises an LED chip 11, an LED chip carrier 17 for carrying the LED chip 11, a lead frame connected to the LED chip carrier 17, at least one metal wire bond 13, a base 15, an external heat sink 26 and a round-shaped transparent cap 1 with a wall 2. In the preferred embodiment of the present invention, the wall 2 is a cylinder wall 2. The metal wire bond 13 is employed to electrically connect the LED chip 11 with the lead frame 12, and the external fin-type heat sink 26 (not shown in FIG. 3 but FIG. 5) is connected to the LED device by performing a molding process so that the cylindrical wall of the LED device is alternatively constituted. As to the chip carrier 17 in the drawing, where the LED chip is attached onto using some conductive paste like silver paste, tin paste, and/or Indium alloy, the lead frame 12 is demonstrated here as pre-molded together with the chip carrier 17 and insulated from the base materials using some insulating sealant-medium like glass in between the wall of the through-hole the lead frame going through the base.

Alternatively, the LED chip 11 is packaged by using a flip chip method instead of utilizing the metal wire bond 13. The round-shaped transparent cap 1 with the wall 2 has a high heat conductivity and covers the base 15 to form a cavity 3 for a-cooling liquid to be filled in, and the cooling liquid directly contacts with the LED chip 11 and the metal wire bond 13. In the preferred embodiment of the present invention, the LED chip 11 and the wire bond 13 comprises an insulating surface (not shown).

The base 15 has either a round shape or a rectangular shape based on the size of the LED device, and is connected to at least two lead frames 12 by performing a preform molding process, such as molding, squeezing, soldering, welding and ejecting processes. The base 15 is composed of an electrically and heat conductive metal, such as copper, copper alloy, aluminum alloy and alloy comprising iron, cobalt and nickel, and an insulating material 25 with a high dielectric constant, such as one of glass, epoxy resin and plastics, is employed to connect the base 15 to the lead frame 12. Alternatively, the base 15 is composed of a non-metal material, such as epoxy resin, acrylic, nitride, butadiene styrene (ABS), glass, polypropylene (PP) and ceramic materials.

The cavity 3 for filling the cooling liquid has either one of a cylinder shape, a spherical shape, a water drip shape or an irregular shape, and the light emitting mode of the LED chip 11 is determined by the characteristics of the cooling liquid. As mentioned in preceding paragraph, the cooling liquid directly contacts with the LED chip 11 and the metal wire bond 13, so that the heat generated during the operation of the LED chip 11 is transferred via the cooling liquid to the round-shaped transparent cap 1 with the wall 2, to the base 115 and to the external heat sink 18, and is accordingly dissipated to the air outside the LED device. Therefore, the temperature of the LED chip 11 during operation is lowered, and the tolerable operating current density of the LED device is increased.

The LED device in the present invention is either a lead frame type LED device or a surface mounting technology (SMT) type LED device, and can be applied by combining multiple LED devices to form a strip or planar light source module in products needing excellent brightness performances. In addition, the packaging method for the LED device in the present invention can also be applied on the packaging of either a vertical emitting type laser diode or an edge emitting type laser diode.

The cooling liquid, which has a thermal capacity higher than that of either one of the solid epoxy resin block 14, silicone rubber or nitrogen atmosphere revealed in the prior art and directly contacts with the LED chip 11 and the wire bond 13, efficiently and rapidly absorb, transfer and dissipate the heat generated by the LED chip 11 during operation to the air outside the LED device, reducing the temperature of the LED chip 11, so as to increase the tolerable operating current density of the LED device, achieving an improved light emitting efficiency and performance of the LED device.

In another embodiment of the present invention, more than one LED chip 11 may be packaged in one LED device according to the product design. The heat generated by the multiple LED chips 11 during operation is absorbed, transferred and dissipated to the air outside the LED device in a same manner as the LED device with single LED chip 11 behaves. For simplicity of description, the detailed structural description of each LED chip 11 with each lead frame 12, wire bond 13 and base 15 and the improved performance of the LED device are neglected.

Alternatively, an insulating film, having a thickness ranging from 0.1 to 50 micrometers, with a high dielectric constant is frequently coated on the surfaces of the LED chip 11 and the lead frame 12 to prevent an oxidation reaction that may occur due to the contact of the cooling liquid with either the LED chip 11 or the lead frame 12. In the preferred embodiment of the present invention, the insulating film is composed of either one of silicon nitride, silicon di-oxide, aluminum oxide, glass, silicone rubber, polymethylmethacrylate (PMMA), epoxy resin, polyamides or polyester resin.

According to the tolerable power design of the LED device, the round-shaped transparent cap 1 may have various shapes, the wall 2 may be composed of either metal or plastic materials, and the base 15 may be either a plastic/PCB base or a base. The heat sink 26 is employed to reinforce the dissipation of the heat generated during the operation of the LED chip 11.

The shape and the volume of the cavity 3 vary depending on the design for the heat dissipating ability and the light-emitting power rating, including emitting angle and illuminating intensity, of the LED device. Since the power rating of the LED device depends on the shape of the LED device, that is the shape of the round-shape transparent cap 1 along with the wall 2 and the LED chip materials. This is another embodiment of this invention which actually provides a practice for rating the Lighting-LED like the way the traditional Light-Bulb does in defining the product specification of the LED device in different power rating.

Transparent liquids with high thermal capacity and refractive index, such as water, inorganic solutions, colloids, organic solutions, emulsions, organic solvents, PFC, PFHC, liquid-state epoxy resin, liquid-state polymers, silicone and glycerin, are frequently utilized as the cooling medium employed in the present invention to transfer and to dissipate the heat generated by the LED chip 11 during operation. Normally, the cooling medium is in a liquid phase under a temperature range from 20° C. to 100° C. The heat P₀ that can be absorbed by the cooling liquid is expressed as the equation below:

P₀=C*m*ΔT/t (1)

wherein C is the thermal capacity of the cooling liquid;

m is the mass of the cooling liquid in gram;

Δ T is the temperature difference of the cooling liquid before and after absorbing the heat generated by the LED chip 11; and

t is the time period for absorbing the heat in second.

Assume that the cooling liquid with a volume of 0.25 cm³ is filled into the cavity 3 of the LED device provided in the present invention. According to the equation (1), the temperature of the cooling liquid rises one degree Celsius after absorbing the heat with a magnitude of 0.25 calories (cal), which is equal to one joule (j). Normally, the time needed for the temperature of the cooling liquid to rise in one unit depends on the thermal capacity and volume of the cooling liquid, as well as on the operating power of the LED device.

The operating power of the LED device is equal to the heat transferred into the cooling liquid and is expressed as the following equation:

P₀=I_{f}*V (2)

wherein I is the forward driving current of the LED device; and f

V is the forward voltage applied on the LED device.

When the operating power of the LED device is 1 watt, a heat of 75 watts is needed for the temperature of the cooling liquid with the volume of 0.25 cm to be changed from 20° C. to 100° C. in 75 seconds. Simultaneously, the temperature of the LED chip 11 is changed from 20° C. to 100° C. However, the latent heat of the cooling liquid enables the temperature of the LED chip 11 to rise slow during the change of the temperature from 20° C. to 100° C. and therefore assures a higher tolerable operating power of the LED device. The heat accumulated in the cooling liquid is transferred to the lead frame 12 due to the convection of the cooling liquid and is subsequently evolved to the air outside the LED device, leading to a stable temperature of the cooling liquid. Consequently, the light-emitting efficiency and the reliability of the LED device are significantly improved.

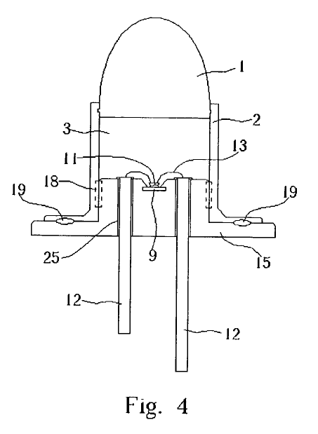

The evolving efficiency of the heat accumulated in the cooling liquid depends on the cross-sectional area and distance of the heat-transferring path as well as on the thermal coefficient of the cooling liquid and the heat conducting material. Assume that the dimensions of the LED device provided in the present invention are equal to a traditional LED device of 5 mm ψ, the lead frame 12 is utilized as the heat-transferring path for most of the heat accumulated in the cooling liquid, the heat-transferring distance is 5 mm long, the cross-sectional area of the heat-transferring path is 0.06 cm² and the lead frame is composed of the copper alloy having a thermal coefficient of approximately 380 W/m/° C., as shown in FIG. 4 of the schematic view of another embodiment of the liquid cooling type LED according to the present invention. The thermal equation is expressed as below:

P_{d}=(S*ΔT)*k/ΔX (3)

wherein P_{d} is the heat evolved to the air outside the LED device from the cooling liquid in watts (W);

S is the smallest cross-sectional area of the heat-transferring path in square meters (m²);

ΔT is the temperature difference between the cooling liquid and the air outside the LED device in degrees Celsius (° C.);

ΔX is the distance of the heat-transferring path in meters (m); and

k is the thermal coefficient of the lead frame 12 in W/m/° C.

According to the equation (3), the heat evolved to the air outside the LED device provided in the present invention from the cooling liquid is 11.4 W as the temperature difference between the cooling liquid and the air outside the LED device is 25° C., which is much higher than the heat of ranging from 0.4 to 1.5 W evolved from the LED device in the prior art. Therefore, the heat-evolving ability of the LED device in the present invention is significantly improved due to the use of the cooling liquid.

Please refer to FIG. 5 of the schematic view of still another embodiment of the liquid cooling type LED device with a fin-type heat sink 26 according to the present invention. As shown in FIG. 5, the fin-type heat sink 26 is employed to increase the heat-evolving area of the LED device and thus reinforces the heat-evolving ability of the LED device, leading to a higher tolerable operating power of the LED device. As the brightness of the LED device is proportionally to the operating power of the LED device, the utilization of the heat sink 26 can significantly increase the brightness performance of the LED device. Therefore, the heat sink 26 can be a tool for specifying LED devices with different brightnesses as well.

The cooling liquid employed in the present invention is either one of water, inorganic solutions, colloids, organic solutions, emulsions, organic solvents, PFC, PFHC, liquid-state epoxy resin, liquid-state polymers, silicone or glycerin, depending on the requirement for the transparency, dielectric constant, refractive index, temperature interval in liquid phase, thermal capacity, thermal coefficient, chemical characteristics, amount of organics or gases contained volatility and thermal expansion coefficient of the cooling liquid. Normally, the thermal capacity of the cooling liquid is preferred to be approximately 1 cal/° C., such as that of the water. Some characteristics of the water is listed for reference as follows:

Refractive index in room temperature: 1.33

Resistivity: 1.0×10¹⁶ Ω

Specific heat: 1.0 cal/(g* ° C.)

Latent heat: 540 cal/g

Thermal coefficient: 0.00134+3.67×10⁻⁶ (t) W/m/° C.

Temperature interval for liquid phase: 0° C.-100° C.

Dielectric constant: 78.48 at 25° C. at the current frequency of 0.57×10⁶ cycles/sec

In contrast to the LED device revealed in the prior art, the LED device provided in the present invention enables the LED chip 11 to remain at a lower temperature the operation with a high driving current density. Therefore, the tolerable operating power is increased to achieve an improved brightness performance.

In addition, the packing method for the LED device in the present invention is similar to the packing method for the LED device in the prior art. Equipments for packaging the LED devices in the prior art can be utilized as well in the mass production of the LED devices in the present invention to save costs for process upgrading. The packaging method comprises the following steps of:

(1) using the conductive adhesive to fix the LED chip 11 on the LED chip carrier 17 on the base 15

(2) using the metal wire bond to either electrically connect either the positive or the negative electrode of the LED chip 11 to the top surface of the lead frame 12, enabling the LED chip 11 to be electrically connected to circuits outside the LED device, or electrically connecting a welding pad on the LED chip 111 to a top surface of an alternative lead frame 12;

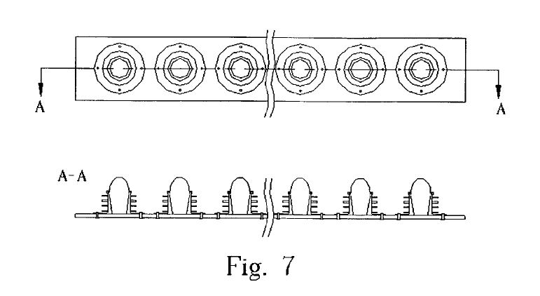

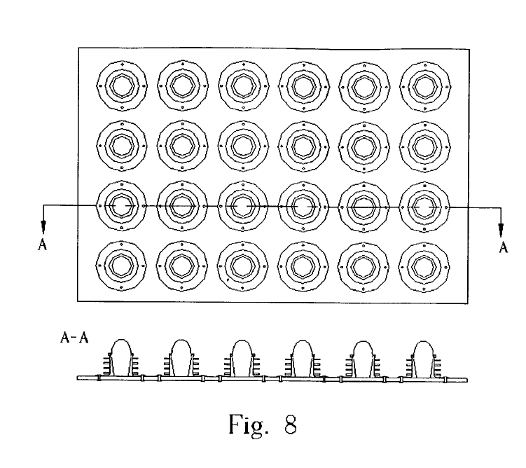

(3) performing a preform molding process to combine the lead frame 12 and the base 15 to form a semi-packaged device with an insulating material with a high dielectric constant, such as either one of glass, epoxy resin and plastics, optionally employed to connect the lead frame 12 to the base in case that the base is composed of a metallic material. A plurality of the semi-packaged device being optionally arranged in either strip or array to form a light-emitting module, as respectively shown in FIG. 7 and FIG. 8, depending on the product requirement;

(4) performing a molding process to connect the transparent round-shape cap 1 to the cylinder wall 2, forming a space for the cooling liquid to be filled in; and

(5) screwing the transparent round-shaped cap 1 with the cylinder wall 2 to the semi-packaged device in a tank filled with the cooling liquid to form the cavity 3 filled with the cooling liquid and coating an adhesive on the connecting gap between the transparent arc-shaped cap 1 with the cylinder wall 2 and the base 15 to prevent a leakage of the cooling liquid.

As discussed in the packaging method revealed in the preceding steps, the LED device is a sealed structure with the cooling liquid filled inside. Therefore, the structure integrity as well as the leak-tightness of the sealing to withstand the pressure of the volume change of the cooling liquid as for a liquid immersion cooling LED device are the most two crucial requirements during the mass production of the LED device.

In another embodiment of the present invention, the LED chip 11 comprises a plurality of solder balls on the top surface of the LED chip 11. The LED chip 11 is therefore electrically flip-connected to either the lead frame 12 or the PCB frame by welding the solder balls with either the lead frame 12 or the PCB frame.

In still another embodiment of the present invention, the LED chip 11 is either a vertical emitting type laser diode chip 11 or a edge emitting type laser diode chip 11. In this case, the packaging method is applicable as well with the cooling liquid with a refractive index greater than 1.0 to assure the performance of the laser diode chip 11. Theoretically, the photo coupling of the laser diode chip 11 with the cooling liquid can lead to an improved light-emitting efficiency of the laser diode chip, and the shortcomings caused by the Tyndall Effect can be adjusted by using optical devices.

In still another embodiment of the present invention, the LED chip 11 is either one of a polymer molecule LED chip 11, a smaller organic LED chip 11 or an organic light emitting display module. In this case, each of the organic LED chip has an independent grid type cavity (not shown) for the cooling liquid to be filled in. In addition, the connection of the outside circuits to the organic LED devices is functional equivalently replaced by traditional circuit design on the PCB/substrate, and terminated with the so-called gold fingers provision for subsequent electrical connection. Since the polymer molecule LED chip and the smaller organic molecule LED chips are frequently applied on a light-emitting panel or a display panel, processes for mass production of either the polymer molecule LED-related products or the smaller organic molecule LED-related products are different from the processes for mass production of the LED-related products. However, the packaging method introduced in preceding paragraphs is still applicable on the packaging of either the polymer molecule LED chip 11 or the smaller organic molecule LED chip 11 by utilizing the specific heat sink 26 to assure an operating temperature of the organic LED device to be lower than 80° C., so as to increase both the reliability and product life of the LED device.

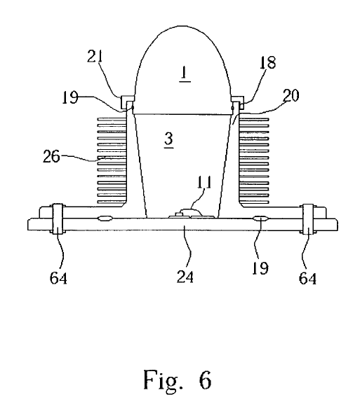

By using the chip on board (COB) technology, the LED chip 11 can be packaged to form either one of a single LED device, a strip LED light module or an array LED light module, as respectively shown in FIG. 6, FIG. 7 and FIG. 8.

In comparison with the LED device revealed in the prior art, the LED device provided in the present invention enables the LED chip 111 to remain at a lower temperature during the operation with a high driving current density by using the cooling liquid. Therefore, the tolerable operating power and driving current density are increased to achieve an improved brightness performance of the LED device. In addition, the LED device in the present invention is packaged by using traditional lead frame 12, which is with acceptable material cost and can be packaged by existent equipments without spending any extra cost caused by the purchase for new equipments. Consequently, products with the LED device in the present invention turn to be much more competitive in the market.

Those skilled in the art will readily observe that numerous modifications and alterations of the device may be made while retaining the teachings of the invention. Accordingly, the above disclosure should be construed as limited only by the metes and bound of the appended claims.

What is claimed is:

1. An immersion cooling type diode device comprising a diode chip, a diode chip carrier for carrying the diode chip, a lead frame connected to the diode chip carrier, a base, a round-shaped transparent cap with a cylinder wall for covering the base to form a cavity, a cooling liquid filled in the cavity, and a heat sink for dissipating heat generated by the diode chip, wherein the cooling liquid directly contacts with the diode chip and the metal wire bond.

2. The immersion cooling type diode device of claim 1 wherein the diode chip is either one of a light emitting diode (LED) chip, a vertical emitting type laser diode chip, an edge emitting type laser diode chip, a polymer molecule LED chip or a smaller organic molecule LED chip.

3. The immersion cooling type diode device of claim 1 wherein the diode chip is packaged by utilizing at least one metal wire bond.

4. The immersion cooling type diode device of claim 1 wherein the diode chip is packaged by using a flip chip method.

5. The immersion cooling type diode device of claim 3 wherein the diode chip and the metal wire bond comprise an insulating surface.

6. The immersion cooling type diode device of claim 1 comprising either one of a transparent concave-shaped, a convex-shaped or a flat-top-shaped cape with a cylindrical wall.

7. The immersion cooling type diode device of claim 6 wherein the cylindrical wall is employed as a heat sink, and a fin-type heat sink is molded to an outer surface of the cylinder wall to reinforce the heat dissipation of the immersion cooling type diode device.

8. The immersion cooling type diode device of claim 1 comprising a plurality of the LED chips.

9. The immersion cooling type diode device of claim 1 wherein the immersion cooling type diode device is either one of a lead frame type LED device or a surface mounting type (SMT) LED device and is applied by combining multiple liquid-cooled LED devices to form either a strip or a planar light source module in LED lighting products needing excellent brightness performances.
